(19) United States
(12) Patent Application Publication
(10) Pub. No.: US 2004/0222473 A1
(43) Pub. Date: Nov. 11, 2004

(54) Semiconductor device

(76) Inventor: Tomomitsu Risaki, Chiba-shi (JP)

Correspondence Address: ADAMS & WILKS, 50 Broadway, 31st Floor, New York, NY, 10004, US

(21) Appl. No.: 10/825,543

(22) Filed: Apr. 14, 2004

(30) Foreign Application Priority Data
Apr. 15, 2003 (JP) 2003-110629

(51) Int. Cl. H01L 29/76; H01L 21/76

(52) U.S. Cl. 257/368; 438/585; 257/412

(57) ABSTRACT

In a metal-oxide semiconductor transistor in which a gate width per unit area can be increased through a method other than microfabrication, there is provided a high driving performance metal-oxide semiconductor transistor in which a single or a plurality of semiconductor devices and another circuit can be consolidated on one chip. The metal-oxide semiconductor transistor includes a plurality of linear concave portions that are arranged in a channel width direction.

### BACKGROUND OF THE INVENTION

1. Field of the Invention

The present invention relates to a semiconductor device required to have high driving performance.

2. Description of the Related Art

A semiconductor integrated circuit includes as its main components a logic circuit unit for performing a logic operation or the like and an output circuit unit for outputting a logic result obtained from the logic circuit at a low impedance. A semiconductor device constituting the output circuit unit needs high driving performance in order that results obtained from the logic circuit unit are outputted with stability to a display device.

Also, when such a semiconductor device is applied to an output unit of a switching regulator, a DC-DC converter, or the like, miniaturization of a coil is demanded so that frequency characteristics of the semiconductor device can be improved. FIG. 2 shows a conventional, typified metal-oxide semiconductor (MOS) structure with high driving performance, which is used for an output circuit unit. As shown in FIG. 2, source regions 8 are collectively formed into a flat shape like teeth of a comb on a surface portion of a first conductive type semiconductor substrate. Then, formed in regular intervals between the source regions 8 shaped like the teeth of a comb are second conductive type drain regions 9. That is, the teeth of a comb for the source regions 8 and those of the drain regions 9 are arranged so as to be opposed to each other at the regular intervals. The intervals correspond to areas for channel formation regions 23. The source regions 8 and the drain regions 9 are surrounded by a device isolator 24. Gate electrodes 2 are also formed like teeth of a comb so as to overlap the channel formation regions 23 through a gate insulating film (not shown). In the semiconductor device, the gate electrodes 2 are formed like the teeth of a comb and have a large channel width to realize high driving performance. However, in terms of the structure, an occupied rate of the semiconductor device on a chip is high.

[Patent Document 1]

JP 11-330465 A (FIG. 1)

When the channel width per unit area in the MOS transistor of FIG. 2 is made still larger, it is necessary to extend a length of the comb shaped gate electrodes 2 and a length of the respective teeth of combs for the source regions and the drain regions (vertical direction in a plane of the drawing) or to narrow a width of the teeth (horizontal direction in the plane of the drawing) and the intervals for increasing the number of the teeth of a comb. Thus, an area occupied by each MOS transistor becomes large.

### SUMMARY OF THE INVENTION

An object of the present invention is to obtain a semiconductor device using a driving MOS transistor that can easily increase a channel width per unit area and facilitates consolidation with a logic circuit unit on one chip.

To solve the above-mentioned conventional problem, according to the present invention, not only the channel width per unit area can be increased through microfabrication but also through a method other than the microfabrication. As a result, driving performance per unit area can be enhanced irrespective of limitations on techniques of the microfabrication.

In addition, through a method similar to that shown in FIG. 4, a single or a plurality of metal-oxide semiconductors with another circuit can be consolidated on one chip with ease.

To attain the above, the following means are devised.

(1) A semiconductor device includes: a semiconductor substrate; high purity regions that are separately provided on a surface portion of the semiconductor substrate; a plurality of the concave portions on the surface portion of the semiconductor substrate between the high purity regions along a direction for lineally connecting the high purity regions; an insulating film provided on the surface portion of the semiconductor substrate including the concave portions between the high purity regions; and a gate electrode provided on the insulating film.

(2) Further, in the semiconductor device, parts of the semiconductor substrate along all convex portions of a concave/convex structure are depleted when a voltage is applied to the gate electrode or in a thermal equilibrium state.

(3) Also, in the semiconductor device, plural semiconductor devices having the concave/convex structure are consolidated on one chip with a logic circuit unit.

### BRIEF DESCRIPTION OF THE DRAWINGS

In the accompanying drawings:

FIGS. 1A to 1C show a basic structure of a MOS transistor according to an embodiment of the present invention, in which FIG. 1A is a plan view of the structure, FIG. 1B is a cross sectional view taken along a line A-A′ of FIG. 1A, and FIG. 1C is a cross sectional view taken along a line B-b′ of FIG. 1A;

FIG. 2 is a top view showing an embodiment of a conventional high driving performance semiconductor device having a general MOS structure;

FIG. 3 is across sectional view of the structure in a direction perpendicular to a channel according to an embodiment of the present invention when the semiconductor device shown in FIG. 1 and another circuit are consolidated on one chip; and

FIG. 4 is an enlarged cross sectional view of FIG. 1C.

### DESCRIPTION OF THE PREFERRED EMBODIMENT

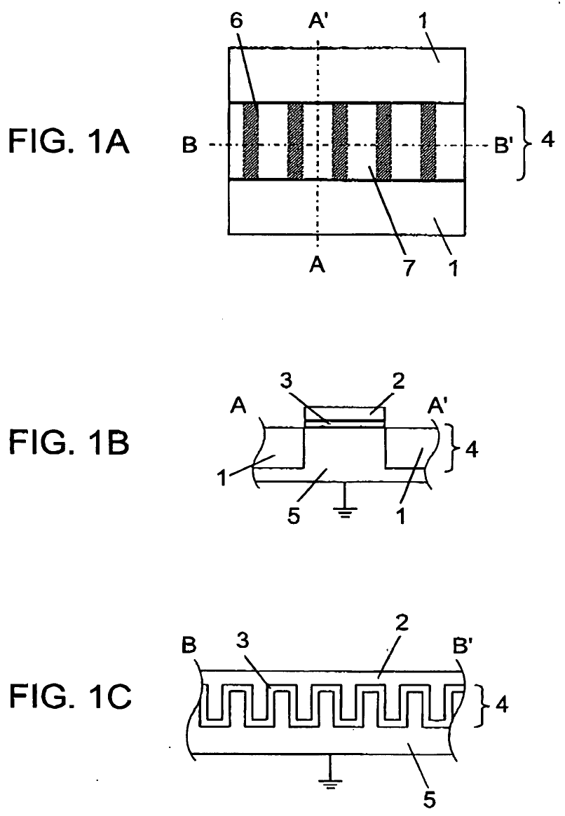

FIG. 1A is a plan view of a basic structure of a MOS transistor according to an embodiment of the present invention, FIG. 1B is a cross sectional view taken along a line A-A′ of FIG. 1A, and FIG. 1C is a cross sectional view taken along a line B-B′ of FIG. 1A. In FIG. 1B, the structure is the same as a general MOS transistor structure. Formed on a surface portion of a P-type semiconductor substrate 5 (of a first conductive type) are N⁺ regions 1 (of a second conductive type) serving as source/drain regions while sandwiching a gate electrode 2. The gate electrode 2 is formed on a surface of the P-type semiconductor substrate 5 through a gate insulating film 3. In a plane of FIG. 1A, a channel length refers to a vertical direction and a channel width refers to a horizontal direction. As shown by shaded parts of FIG. 1A, each concave portion 6 is formed along the channel length direction while being substantially connected to the N⁺ regions 1 at its both ends, in channel formation regions between the N⁺ regions 1 of the second conductive type serving as source/drain regions. Further, a plurality of the linearly formed concave portions 6 are arranged in the channel width direction. That is, as shown in FIG. 1C, concave/convex structures 4 are formed on the surface of the P-type semiconductor substrate 5.

Decrease in pitch intervals of the concave/convex structures 4 through microfabrication enables increase in channel width per unit area. Also, the channel width per unit area can be made larger by increasing a depth of the concave portion 6 of the concave/convex structure 4. Thus, driving performance per unit area can be enhanced through the microfabrication.

Next, without referring to the drawings, a brief description is given to how the concave/convex structure 4 and the MOS transistor of FIGS. 1A to 1C are formed. The concave portion 6 as shown in FIG. 1A to 1C is formed by dry etching by using a mask on the channel formation region (between the source/drain regions) surface of the P-type semiconductor substrate 5. Then, through the gate insulating film 3, the gate electrode 2 is formed on the concave/convex structure 4 surface with the mask. The gate electrode 2 is used as a mask to form the source/drain regions.

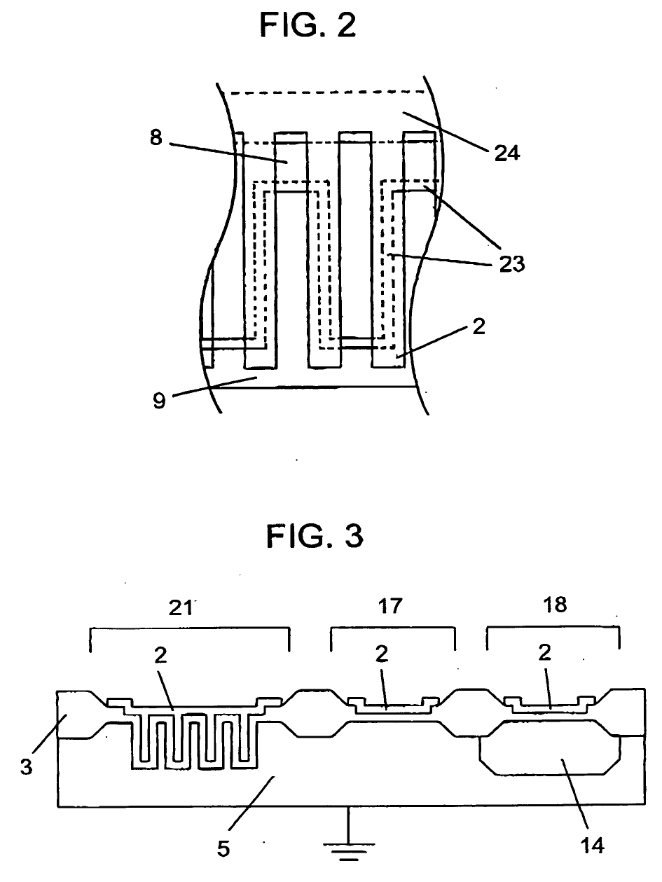

To enhance the channel width per unit area in the conventional high driving performance semiconductor device shown in FIG. 2, microfabrication techniques are required in particular. However, the present invention does not require costly and specially complicated microfabrication techniques, thereby allowing a product to be provided at a lower price than the conventional semiconductor device.

Now, a depletion layer 16 formed in the structure of the present invention is described. As shown in FIG. 4, when a width of a convex portion 7 between two concave portions 6 of the concave/convex structure 4 is relatively small, depletion can be achieved along all parts of the P-type semiconductor substrate 5 in the convex portion 7. Thus, parasitic capacitance between the gate electrode 2 and the P-type semiconductor substrate 5 is reduced, thereby enhancing high frequency characteristics and subthreshold characteristics.

Subsequently, a case is described where a MOS transistor with high driving performance (high voltage) and a low voltage MOS transistor with low output are consolidated on one chip. Consolidation of the conventional high driving performance MOS transistor shown in FIG. 2 with a low voltage MOS transistor on one chip can be carried out relatively easily. However, considering limitations on microfabrication techniques, the area needs to be enlarged for attaining high driving performance.

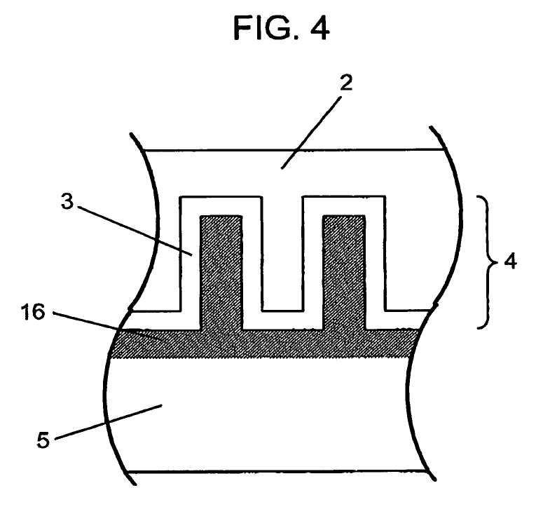

On the other hand, according to an embodiment shown in FIG. 3, irrespective of the number of the semiconductor devices having the structure of the present invention, the semiconductor device in which the logic circuit unit (that is composed of a low output n-type MOS transistor 17 and a p-type MOS transistor 18) and the high driving performance MOS transistor shown in FIG. 1 are consolidated on one chip can be obtained with ease. In addition, driving performance per unit area can be enhanced as compared with the conventional semiconductor device shown in FIG. 2. Note that the p-type MOS transistor 18 is formed in an N-type well 14 formed in the P-type semiconductor substrate 5.

Moreover, the channel length of the semiconductor device according to the present invention is easily changed in accordance with a voltage band of an output terminal. That is, the semiconductor device can cope with such a situation that in a multi-output power source IC, the channel length is long when a voltage is relatively high, and the channel length is short when a voltage is low, and thus has large flexibility in design.

As set forth hereinabove, driving performance per unit area can be enhanced through a method other than microfabrication, such as a method of increasing the depth of the concave/convex portions of the semiconductor device of the present invention.

Further, according to the semiconductor device having the structure of the present invention, a single or a plurality of the semiconductor devices and the logic circuit unit can be consolidated on one chip with ease. Accordingly, the flexibility in design increases.

What is claimed is:

1. A semiconductor device comprising;
a semiconductor substrate;
source/drain regions that are separately provided on a surface portion of the semiconductor substrate;
a concave portion formed in a channel length direction on the surface portion of the semiconductor substrate between the source/drain regions so as to lineally connect the source/drain regions, a plurality of the concave portions being arranged in a channel width direction;
an insulating film provided on the surface portion of the semiconductor substrate including the concave portions between the source/drain regions; and
a gate electrode provided on the insulating film.

2. A semiconductor device according to claim 1, wherein parts of the semiconductor substrate along all convex portions of a concave/convex structure are depleted.

3. A semiconductor device according to claim 1, wherein plural semiconductor devices having the concave/convex structure are consolidated on one chip with a MOS transistor for a logic circuit unit.
